(19) United States
(12) Patent Application Publication
(10) Pub. No.: US 2026/0009134 A1
(43) Pub. Date: Jan. 8, 2026

(54) SUBSTRATE PROCESSING APPARATUS, EJECTION APPARATUS, SUBSTRATE PROCESSING METHOD, METHOD OF MANUFACTURING SEMICONDUCTOR DEVICE AND NON-TRANSITORY COMPUTER-READABLE RECORDING MEDIUM

(71) Applicant: Kokusai Electric Corporation, Tokyo (JP)

(72) Inventors: Taketoshi MORIYA, Toyama (JP); Yusaku OKAJIMA, Toyama (JP); Mika URUSHIHARA, Toyama (JP)

(21) Appl. No.: 19/234,513

(22) Filed: Jun. 11, 2025

(30) Foreign Application Priority Data
Jul. 8, 2024 (JP) 2024-109409

(51) Int. Cl. C23C 16/455

(52) U.S. Cl. CPC C23C 16/45578

(57) ABSTRACT

It is possible to increase a flow path area of a process gas. There is provided a technique that includes: an ejection apparatus beside a substrate, extending along a direction perpendicular to the substrate, and configured to eject a gas onto the substrate, wherein the ejection apparatus includes: a first nozzle and a second nozzle, and wherein each of the first nozzle and the second nozzle is provided with: a flat surface facing the substrate; two surfaces connected to both sides of the flat surface; a plurality of first ejection holes arranged on the flat surface along a direction parallel to the substrate and configured to eject the gas substantially in a same direction; and a second ejection hole arranged on at least one of the two surfaces and configured to eject the gas in a direction inclined with respect to the same direction.

### CROSS REFERENCE TO RELATED APPLICATIONS

This non-provisional U.S. patent application is based on and claims priority under 35 U.S.C. § 119 (a)-(d) to Japanese Patent Application No. 2024-109409, filed on Jul. 8, 2024, the entire contents of which are hereby incorporated by reference.

### TECHNICAL FIELD

The present disclosure relates to a substrate processing apparatus, an ejection apparatus, a substrate processing method, a method of manufacturing a semiconductor device and a non-transitory computer-readable recording medium.

### BACKGROUND

In a method of manufacturing a semiconductor device, as an example of an apparatus capable of forming an oxide film or a metal film on a substrate (hereinafter, also referred to as a “wafer”), a vertical type substrate processing apparatus may be used. In the vertical type substrate processing apparatus, a boat is provided as a substrate retainer capable of supporting (or holding) a plurality of wafers in a multistage manner in a process vessel. The wafers (substrates) are processed by supplying a process gas to each of the substrates while the substrates are supported by the boat.

However, in such a method mentioned above, the process gas is supplied toward a center of each of the wafers. Thereby, a flow path area of the process gas may be reduced. In such a case, depending on a process, it may be difficult to sufficiently (or appropriately) control a flow of the process gas inside the process vessel.

### SUMMARY

According to the present disclosure, there is provided a technique capable of increasing a flow path area of a process gas.

According to an embodiment of the present disclosure, there is provided a technique that includes: an ejection apparatus provided in a process vessel beside an edge of a substrate accommodated in the process vessel, extending along a direction perpendicular to the substrate, and configured to eject a gas onto the substrate, wherein the ejection apparatus includes: a first nozzle of a cylindrical shape; and a second nozzle of a cylindrical shape, and wherein each of the first nozzle and the second nozzle is provided with: a flat surface facing the substrate; two surfaces connected to both sides of the flat surface; a plurality of first ejection holes arranged on the flat surface along a direction parallel to the substrate and configured to eject the gas substantially in a same direction; and a second ejection hole arranged on at least one of the two surfaces and configured to eject the gas in a direction inclined with respect to the same direction.

### BRIEF DESCRIPTION OF THE DRAWINGS

FIG. 1 is a diagram schematically illustrating a vertical cross-section of a substrate processing apparatus according to one or more embodiments of the present disclosure.

FIG. 2 is a diagram schematically illustrating a horizontal cross-section taken along a line A-A of the substrate processing apparatus shown in FIG. 1.

FIG. 3 is a diagram schematically illustrating a vertical cross-section taken along a line B-B of the substrate processing apparatus shown in FIG. 2.

FIG. 4 is a diagram schematically illustrating an enlarged cross-section of a part of the substrate processing apparatus shown in FIG. 3.

FIG. 5 is a diagram schematically illustrating a perspective view of an ejection apparatus of the substrate processing apparatus according to the embodiments of the present disclosure.

FIG. 6 is a block diagram schematically illustrating a configuration of a controller and related components of the substrate processing apparatus according to the embodiments of the present disclosure.

FIG. 7 is a flow chart schematically illustrating a substrate processing according to the embodiments of the present disclosure.

FIG. 8 is a graph schematically illustrating a relationship between a position and a pressure of a gas nozzle according to the embodiments of the present disclosure.

FIG. 9A is a diagram schematically illustrating a pressure distribution related to the gas nozzle when a second ejection hole is not provided, FIG. 9B is a diagram schematically illustrating a pressure distribution related to the gas nozzle when the second ejection hole is provided, FIG. 9C is a diagram schematically illustrating a flow velocity distribution related to the gas nozzle when the second ejection hole is not provided, and FIG. 9D is a diagram schematically illustrating a flow velocity distribution related to the gas nozzle when the second ejection hole is provided.

### DETAILED DESCRIPTION

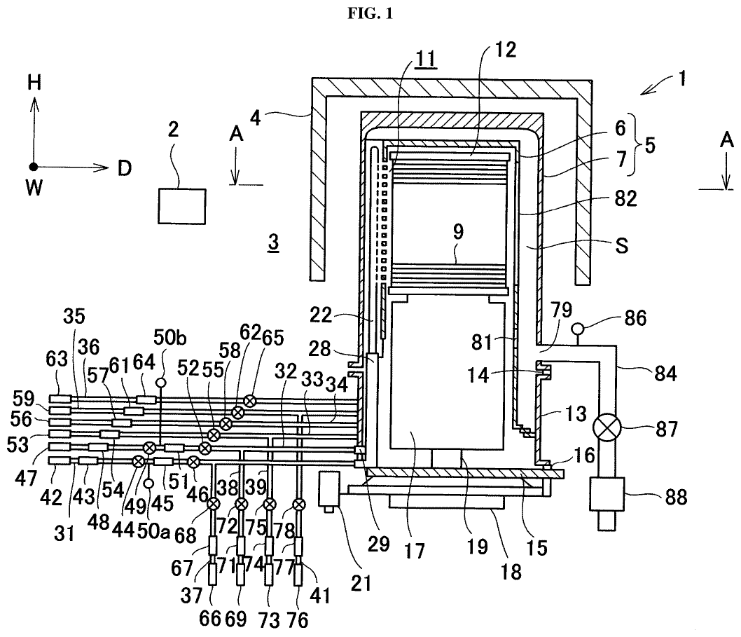

Hereinafter, one or more embodiments (also simply referred to as “embodiments”) of the technique of the present disclosure will be described in detail mainly with reference to FIGS. 1 to 9D. The drawings used in the following descriptions are all schematic. For example, a relationship between dimensions of each component and a ratio of each component shown in the drawing may not always match the actual ones. In addition, even between the drawings, the relationship between the dimensions of each component and the ratio of each component may not always match.

Further, the number of each component described in the present specification is not limited to one, and the number of each component may be two or more unless otherwise specified in the present specification. In addition, the same or similar reference numerals represent the same or similar components in the drawings. Thus, each component is described with reference to the drawing in which it first appears, and redundant descriptions related thereto will be omitted unless particularly necessary.

In the present specification, the term “wafer” may refer to “a wafer itself” or may refer to “a wafer and a stacked structure (aggregated structure) of a predetermined layer (or layers) or a film (or films) formed on a surface of the wafer”. In addition, in the present specification, the term “a surface of a wafer” may refer to “a surface of a wafer itself” or may refer to “a surface of a predetermined layer (or layers) or a film (or films) formed on a wafer”. Thus, in the present specification, the term “forming a predetermined layer (or a film) on a wafer” may refer to “forming a predetermined layer (or a film) on a surface of a wafer itself” or may refer to “forming a predetermined layer (or a film) on a surface of another layer (or another film) formed on a wafer”. In the present specification, the terms “substrate” and “wafer” may be used as substantially the same meaning.

In the present specification, the term “agent” may contain at least one selected from the group of a gaseous substance and a liquid substance. The liquid substance may contain a mist substance. That is, each of a film-forming agent, a modifying agent and an etching agent may contain a gaseous substance, may contain a liquid substance such as a mist substance, or may contain both of the gaseous substance and the liquid substance.

In the present specification, a notation of a numerical range such as “from 1 Pa to 2,000 Pa” means that a lower limit and an upper limit are included in the numerical range. Therefore, for example, a numerical range “from 1 Pa to 2,000 Pa” means a range equal to or higher than 1 Pa and equal to or less than 2,000 Pa. The same also applies to other numerical ranges described in the present specification. In addition, when a numerical range (which is related to a supply of a substance such as a gas) includes “0”, it refers to a case where the substance such as the gas is not supplied. For example, when a supply flow rate of the gas is zero (0) slm, it refers to a case where the gas is not supplied. The same also applies to the following descriptions.

### <Overall Configuration of Substrate Processing Apparatus>

First, an overall configuration of a substrate processing apparatus 1 according to the present embodiments will be described with reference to FIGS. 1 to 6. In the FIGS. 1 to 3, an up-down direction H of an apparatus (that is, the substrate processing apparatus 1) indicates a vertical direction, a width direction W of the apparatus indicates a horizontal direction, and a depth direction D of the apparatus indicates another horizontal direction.

As shown in FIG. 1, the substrate processing apparatus 1 according to the present embodiments includes a controller 2 and a process furnace 3. The controller 2 is configured to control components constituting the substrate processing apparatus 1. The process furnace 3 includes a heater 4 serving as a heating structure (heating apparatus). The heater 4 is of a cylindrical shape, and is installed in the up-down direction H of the apparatus while being supported by a heater base (not shown). The heater 4 also functions as an activator capable of activating a process gas by a heat. The controller 2 will be described in detail later.

A reaction tube 5 constituting a process vessel is vertically provided in an inner side of the heater 4 to be aligned in a manner concentric with the heater 4. The process vessel is configured such that a plurality of substrates can be accommodated therein. For example, the reaction tube 5 is made of a heat resistant material such as quartz (SiO₂) and silicon carbide (SiC). For example, the substrate processing apparatus 1 is a so-called “hot wall type substrate processing apparatus”.

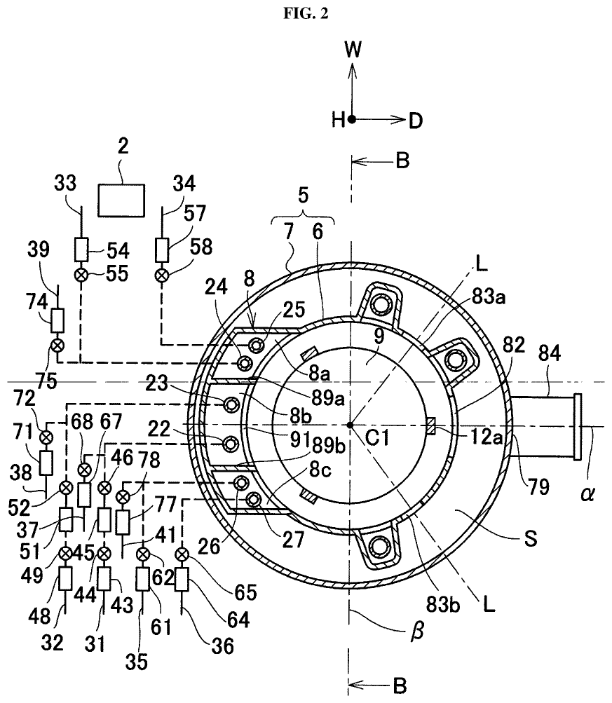

As shown in FIG. 2, the reaction tube 5 includes: an inner tube 6 of a cylindrical shape and an outer tube 7 of a cylindrical shape arranged to surround the inner tube 6. That is, the outer tube 7 constitutes the reaction tube 5 together with the inner tube 6. Since the outer tube 7 surrounds the inner tube 6, a gap serving as an exhaust space S is provided between cylinders (cylindrical portions) of the inner tube 6 and the outer tube 7. The inner tube 6 is provided in a manner concentric with the outer tube 7. The inner tube 6 serves as an example of a tube structure.

The inner tube 6 includes a side wall serving as the cylinder mentioned above. An upper portion of the side wall is covered by a ceiling. The cylinder of the inner tube 6 is configured such that that the plurality of substrates can be accommodated therein. Specifically, as shown in FIG. 1, the inner tube 6 is provided with an open lower end and a closed upper end (that is, the ceiling). The upper end of the inner tube 6 is closed by a flat wall body. In addition, the outer tube 7 is also provided with an open lower end and a closed upper end (that is, the ceiling). The upper end of the outer tube 7 is closed by a flat wall body. In addition, as shown in FIG. 2, a supply buffer 8 serving as a nozzle chamber is provided in the exhaust space S formed between the inner tube 6 and the outer tube 7. The supply buffer 8 will be described in detail later.

As shown in FIG. 1, a process chamber 11 is provided inside the inner tube 6. A plurality of wafers 9 serving as the substrates are processed in the process chamber 11. Hereinafter, each of the wafers 9 may also be referred to as a “wafer 9”. The process chamber 11 is also configured such that a boat 12 serving as an example of a substrate retainer can be accommodated therein. The substrate retainer is configured such that the wafers 9 can be accommodated therein while arranged vertically in a multistage manner in a horizontal orientation with their centers aligned, and the inner tube 6 surrounds the wafers 9 accommodated in the boat 12. The wafers 9 are arranged inside the cylinder of the inner tube 6 along an axial direction of the cylinder of the inner tube 6. The inner tube 6 will be described in detail later.

A lower end of the reaction tube 5 (that is, the lower end of the inner tube 6 and/or the lower end of the outer tube 7) is supported by a manifold 13 of a cylindrical shape. For example, the manifold 13 is made of a metal such as a nickel alloy and stainless steel, or is made of a heat resistant material such as SiO₂ and SiC. A flange is formed at an upper end of the manifold 13, and the lower end of the outer tube 7 is provided on the flange. An airtight seal 14 such as an O-ring is arranged between the flange and the lower end of the outer tube 7. Thereby, it is possible to maintain an inside (inner portion) of the reaction tube 5 airtight.

A seal cap 15 is airtightly attached (or provided) to an opening at a lower end of the manifold 13 via an airtight seal 16 such as an O-ring. Thereby, it is possible to maintain an opening at the lower end of the reaction tube 5 (that is, the opening at the lower end of the manifold 13) airtight. For example, the seal cap 15 is of a disk shape, and is made of a metal such as a nickel alloy and stainless steel. For example, the seal cap 15 may be configured such that an outside (outer portion) thereof is covered with a heat resistant material such as SiO₂ and SiC.

A boat support table (also referred to as a “boat support stand”) 17 configured to support the boat 12 is provided on the seal cap 15. For example, the boat support table 17 is made of a heat resistant material such as SiO₂ and SiC, and functions as a heat insulator.

The boat 12 is vertically provided on the boat support table 17. For example, the boat 12 is made of a heat resistant material such as SiO₂ and SiC. As shown in FIG. 1, the boat 12 includes: a bottom plate (not shown) fixed to the boat support table 17; a top plate (not shown) disposed above the bottom plate; and a plurality of support columns 12a (see FIG. 2) provided between the bottom plate and the top plate.

The boat 12 accommodates the wafers 9 to be processed in the process chamber 11 inside the inner tube 6. As shown in FIG. 1, the wafers 9 are supported by the support columns 12a of the boat 12 while arranged with a fixed interval (distance) therebetween and in a horizontal orientation with their centers aligned. A loading direction (stacking direction) of the wafers 9 is an axial direction of the reaction tube 5. In other words, the centers of the wafers 9 are aligned with a central axis of the boat 12. The central axis of the boat 12 coincides with a central axis of the reaction tube 5.

A rotator (which is a rotating structure) 18 configured to rotate the boat 12 is provided below the seal cap 15. A rotating shaft 19 of the rotator 18 is connected to the boat support table 17 by penetrating the seal cap 15. By rotating the boat 12 via the boat support table 17, the rotator 18 rotates the wafers 9.

The seal cap 15 is elevated and lowered in the vertical direction by an elevator 21 serving as an elevating structure provided outside the reaction tube 5. Thereby, the boat 12 can be transferred (loaded) into and transferred (unloaded) out of the process chamber 11.

A plurality of nozzle supports (nozzle support structures) are provided in the manifold 13 so as to penetrate the manifold 13. For example, the nozzle supports are configured such that a plurality of gas nozzles through which gases are supplied into the process chamber 11 can be supported by the nozzle supports. For example, the nozzle supports are configured such that a first gas nozzle 22, a second gas nozzle 23, a third gas nozzle 24, a fourth gas nozzle 25, a fifth gas nozzle 26 and a sixth gas nozzle 27 can be supported by the nozzle supports. According to the present example, for example, the nozzle supports are provided corresponding to the gas nozzles. However, in FIG. 1, the first gas nozzle 22 among the gas nozzles and a first nozzle support 28 and a second nozzle support 29 among the nozzle supports are illustrated. For example, each of the nozzle supports is made of a material such as a nickel alloy and stainless steel. In the following descriptions, each of the gas nozzles may also be simply referred to as a “nozzle”, and each of the nozzle supports may also be referred to as a “nozzle support”. Each of the gas nozzles is provided beside an edge (side) of the wafer 9 accommodated in the boat 12, and extends in a direction perpendicular to the wafer 9.

Gas supply pipes 31, 32, 33, 34, 35 and 36 through which the gases are supplied into the process chamber 11 are connected to first ends (first end portions) of the nozzle supports, respectively. In addition, the first gas nozzle 22, the second gas nozzle 23, the third gas nozzle 24, the fourth gas nozzle 25, the fifth gas nozzle 26 and the sixth gas nozzle 27 are connected to second ends (second end portions) of the nozzle supports, respectively. In addition, a gas supply pipe 37 is connected to the gas supply pipe 31, a gas supply pipe 38 is connected to the gas supply pipe 32, a gas supply pipe 39 is connected to the gas supply pipe 33, and a gas supply pipe 41 is connected to the gas supply pipe 35. For example, each of the gas nozzles 22 to 27 is made of a heat resistant material such as SiO₂ and SiC. Each of the gas nozzles 22 to 27 will be described in detail later.

### <Gas Supply Pipes>

The gas supply pipes 31 and 37 are connected to the first gas nozzle 22 via the first nozzle support 28. The gas supply pipes 32 and 38 are connected to the second gas nozzle 23 via the second nozzle support 29. The gas supply pipes 33 and 39 are connected to the third gas nozzle 24 via another nozzle support.

In addition, the gas supply pipe 34 is connected to the fourth gas nozzle 25 via another nozzle support. The gas supply pipes 35 and 41 are connected to the fifth gas nozzle 26 via another nozzle support. The gas supply pipe 36 is connected to the sixth gas nozzle 27 via another nozzle support.

A source gas supply source 42 configured to supply a first source gas serving as one of process gases, a mass flow controllers (also simply referred to as an “MFC”) 43 serving as an example of a flow rate controller, a valve 44 serving as an opening/closing valve, a tank 45 and a valve 46 are sequentially installed at the gas supply pipe 31 in this order from an upstream side to a downstream side of the gas supply pipe 31 in a gas flow direction. In addition, a source gas supply source 47 configured to supply the first source gas serving as one of the process gases, an MFC 48, a valve 49, a tank 51 and a valve 52 are sequentially installed at the gas supply pipe 32 in this order from an upstream side to a downstream side of the gas supply pipe 32 in the gas flow direction. Hereinafter, each of the process gases may also be referred to as the “process gas”.

The MFC 43 and the MFC 48 serve as a pair of flow rate controllers according to the present disclosure configured to supply the gas (that is, the first source gas) to a pair of tanks (that is, the tank 45 and the tank 51) at pre-set flow rates, respectively. The pre-set flow rates are set such that a reference accumulation amount serving as a target amount of the gas can be supplied. In addition, the valve 46 serves as an opening/closing valve configured to control a fluid communication of the gas between the first gas nozzle 22 and the tank 45, and the valve 52 serves as an opening/closing valve configured to control a fluid communication of the gas between the second gas nozzle 23 and the tank 51. The valve 46 and the valve 52 serve as a pair of opening/closing valves according to the present disclosure.

Further, when a flow rate of the gas cannot be limited to a pre-set flow rate, a control valve (not shown) provided inside each of the MFCs 43 and 48 is fully open or fully closed. Such a state may also be referred to as a “saturated state” or an “uncontrollable state”. In the present disclosure, when the flow rate of the gas cannot be limited to the pre-set flow rate, the control valve inside each of the MFCs 43 and 48 may be fully open or fully closed, or may be in a state between fully open and fully closed.

Although not shown, each of the MFCs 43 and 48 is provided with an orifice and the control valve configured to control a pressure of the gas on a primary side of the orifice. Each of the MFCs 43 and 48 uses a choked flow of the orifice to control the flow rate of the gas.

The tanks 45 and 51 are configured to store the first source gas alone such that the first source gas supplied from the source gas supply sources 42 and 47 is not mixed with a carrier gas.

In addition, pressure sensors 50a and 50b are provided on upstream sides of the tanks 45 and 51, respectively. The pressure sensors 50a and 50b serve as a pair of pressure gauges (pressure meters) according to the present disclosure. The pressure sensors 50a and 50b are configured to measure pressures (inner pressures) of the tanks 45 and 51, respectively, while accumulating the gas.

A source gas supply source 53 configured to supply a second source gas serving as one of the process gases, an MFC 54 and a valve 55 are sequentially installed at the gas supply pipe 33 in this order from an upstream side to a downstream side of the gas supply pipe 33 in the gas flow direction. In addition, an assist gas supply source 56 configured to supply an assist gas serving as one of the process gases, an MFC 57 and a valve 58 are sequentially installed at the gas supply pipe 34 in this order from an upstream side to a downstream side of the gas supply pipe 34 in the gas flow direction. The second source gas is also used as a reactive gas, and the assist gas is a gas different from both the first source gas and the second source gas.

A source gas supply source 59 configured to supply the second source gas serving as one of the process gases, an MFC 61 and a valve 62 are sequentially installed at the gas supply pipe 35 in this order from an upstream side to a downstream side of the gas supply pipe 35 in the gas flow direction. In addition, an assist gas supply source 63 configured to supply the assist gas serving as one of the process gases, an MFC 64 and a valve 65 are sequentially installed at the gas supply pipe 36 in this order from an upstream side to a downstream side of the gas supply pipe 36 in the gas flow direction.

The gas supply pipe 37 through which an inert gas is supplied is connected to the gas supply pipe 31 at a downstream side of the valve 46. An inert gas supply source 66 configured to supply the inert gas serving as one of the process gases, an MFC 67 and a valve 68 are sequentially installed at the gas supply pipe 37 in this order from an upstream side to a downstream side of the gas supply pipe 37 in the gas flow direction. The gas supply pipe 38 through which the inert gas is supplied is connected to the gas supply pipe 32 at a downstream side of the valve 52. An inert gas supply source 69 configured to supply the inert gas serving as one of the process gases, an MFC 71 and a valve 72 are sequentially installed at the gas supply pipe 38 in this order from an upstream side to a downstream side of the gas supply pipe 38 in the gas flow direction.

In addition, the gas supply pipe 39 through which the inert gas is supplied is connected to the gas supply pipe 33 at a downstream side of the valve 55. An inert gas supply source 73 configured to supply the inert gas serving as one of the process gases, an MFC 74 and a valve 75 are sequentially installed at the gas supply pipe 39 in this order from an upstream side to a downstream side of the gas supply pipe 39 in the gas flow direction. The gas supply pipe 41 through which the inert gas is supplied is connected to the gas supply pipe 35 at a downstream side of the valve 62. An inert gas supply source 76 configured to supply the inert gas serving as one of the process gases, an MFC 77 and a valve 78 are sequentially installed at the gas supply pipe 41 in this order from an upstream side to a downstream side of the gas supply pipe 41 in the gas flow direction. For example, the assist gas supply sources 56 and 63 and the inert gas supply sources 66, 69, 73 and 76 are connected to a common supply source.

### <Supply System to First Gas Nozzle 22>

A first source gas supply system (also referred to as a “first gas supplier”) configured to supply the first source gas to the first gas nozzle 22 is constituted mainly by the gas supply pipe 31, the gas supply pipe 37, the MFC 43, the MFC 67, the tank 45, the valve 44, the valve 46 and the valve 68. The first source gas supply system configured to supply the first source gas to the first gas nozzle 22 may further include the source gas supply source 42 and the inert gas supply source 66.

### <Supply System to Second Gas Nozzle 23>

A first source gas supply system (also referred to as a “first gas supplier”) configured to supply the first source gas to the second gas nozzle 23 is constituted mainly by the gas supply pipe 32, the gas supply pipe 38, the MFC 48, the MFC 71, the tank 51, the valve 49, the valve 52 and the valve 72. The first source gas supply system configured to supply the first source gas to the second gas nozzle 23 may further include the source gas supply source 47 and the inert gas supply source 69.

### <Supply System to Third Gas Nozzle 24>

A second source gas supply system (also referred to as a “second gas supplier”) configured to supply the second source gas to the third gas nozzle 24 is constituted mainly by the gas supply pipe 33, the gas supply pipe 39, the MFC 54, the MFC 74, the valve 55 and the valve 75. The second source gas supply system configured to supply the second source gas to the third gas nozzle 24 may further include the source gas supply source 53 and the inert gas supply source 73.

### <Supply System to Fourth Gas Nozzle 25>

An assist gas supply system (also referred to as an “assist gas supplier”) configured to supply the assist gas only to an upper dummy region of two side dummy regions described later is constituted mainly by the gas supply pipe 34, the MFC 57 and the valve 58. The assist gas supply system configured to supply the assist gas to the upper dummy region alone may further include the assist gas supply source 56.

### <Supply System to Fifth Gas Nozzle 26>

A second source gas supply system (also referred to as a “second gas supplier”) configured to supply the second source gas to the fifth gas nozzle 26 is constituted mainly by the gas supply pipe 35, the gas supply pipe 41, the MFC 61, the MFC 77, the valve 62 and the valve 78. The second source gas supply system configured to supply the second source gas to the fifth gas nozzle 26 may further include the source gas supply source 59 and the inert gas supply source 76.

### <Supply System to Sixth Gas Nozzle 27>

An assist gas supply system (also referred to as an “assist gas supplier”) configured to supply the assist gas only to a lower dummy region of the two side dummy regions described later is constituted mainly by the gas supply pipe 36, the MFC 64, and the valve 65. The assist gas supply system configured to supply the assist gas to the lower dummy region alone may further include the assist gas supply source 63.

### <Tanks>

The tanks 45 and 51 are configured such that volumes thereof are substantially the same. The tanks 45 and 51 can store the source gas alone so that the source gas is not mixed with the carrier gas. The tanks 45 and 51 are configured to substantially (approximately) simultaneously supply the source gas stored therein to the first gas nozzle 22 and the second gas nozzle 23 through the opening/closing valves, respectively, in a pulse manner. The tanks 45 and 51 serve as a pair of tanks according to the present disclosure. The inner pressure of each of the tanks 45 and 51 is usually below an atmospheric pressure. The inner pressure of each of the tanks 45 and 51 may vary depending on a vapor pressure of the source gas. As the tanks 45 and 51, an isothermal tank filled with a substance such as a metal wool and a filament may be used.

That is, according to the present embodiments, it is possible to perform a flash supply of the source gas whose concentration is high. In the flash supply, the source gas stored in the tanks 45 and 51 is supplied at a high flow rate from the tanks 45 and 51 toward the reaction tube 5. The source gas supplied at a high flow rate may also be referred to as the “source gas supplied in a flash flow manner”. The source gas supplied in the flash flow manner flows at a relatively high speed over a surface of the wafer 9 inside the cylinder of the inner tube 6 during a film forming process described later.

By supplying the source gas in the flash flow manner, during the film forming process, an entire surface of the wafer 9 is exposed to a flow of the source gas whose flow velocity is high. Using the flow of the source gas whose flow velocity is high is one of the most effective methods to promote a gas replacement inside a fine structure such as a trench and a hole formed on the surface of the wafer 9, and is particularly useful in processing a patterned wafer with a high aspect ratio.

In addition, the embodiments of the present disclosure are not limited to the flash supply of the source gas (that is, a supply of the source gas in the flash flow manner). For example, the embodiments of the present disclosure may also be applied to a supply of a substance (such as ammonia (NH₃) serving as a purge gas) at a large flow rate using a general MFC.

### <Exhaust System>

A main exhaust port (also referred to as a “primary exhaust port”) 79 is provided at the outer tube 7 of the reaction tube 5. The main exhaust port 79 is provided below an exhaust port 81 of the inner tube 6. A main exhaust slit (also referred to as a “primary exhaust slit”) 82 serving as a first exhaust structure is provided at the inner tube 6 of the reaction tube 5. In other words, the reaction tube 5 is provided with the main exhaust slit 82 on a side surface thereof.

As shown in FIG. 2, the main exhaust port 79 is arranged so as to be aligned on the same straight line as the main exhaust slit 82 when viewed from above. As shown in FIG. 2, each of two subsidiary exhaust ports (also referred to as “secondary exhaust ports”) are arranged so as to be aligned on the same straight line as each of subsidiary exhaust slits (also referred to as “secondary exhaust slits”) 83a and 83b corresponding thereto when viewed from above. The subsidiary exhaust slits 83a and 83b correspond to a second exhaust structure of the present disclosure.

The main exhaust port 79 is configured to communicate between the exhaust space S and an outside (outer portion) of the reaction tube 5. The main exhaust port 79 corresponds to an exhaust port of the present disclosure. An exhaust duct 84 through which the source gas is sent to the outside of the reaction tube 5 is connected to the main exhaust port 79.

A vacuum pump 88 serving as a vacuum exhaust apparatus is connected to the exhaust duct 84 via a pressure sensor 86 and an APC (Automatic Pressure Controller) valve 87. The pressure sensor 86 is configured to detect a pressure (inner pressure) of the process chamber 11, and the APC (Auto Pressure Controller) valve 87 serves as a pressure regulator (which is a pressure adjusting structure). The exhaust duct 84 downstream of the vacuum pump 88 is connected to a component such as a waste gas treatment apparatus (not shown). With such a configuration, by controlling an output of the vacuum pump 88 and an opening degree of the APC valve 87, it is possible to vacuum-exhaust the process chamber 11 such that the inner pressure of the process chamber 11 can be adjusted (or set) to a predetermined pressure (that is, a vacuum degree).

A main exhaust system (also referred to as a “primary exhaust system”, a “main exhauster” or a “primary exhauster”) is constituted mainly by the exhaust duct 84, the APC valve 87, and the pressure sensor 86. The main exhaust system may further include the vacuum pump 88.

In addition, a temperature sensor (not shown) serving as a temperature detector is provided in the reaction tube 5. By adjusting a power supplied to the heater 4 based on temperature information detected by the temperature sensor, it is possible to set (or adjust) a distribution of the inner temperature of the process chamber 11 to a desired temperature distribution.

With such a configuration, in the process furnace 3, the boat 12 supporting the wafers 9 (which are to be batch processed) in a multistage manner is transferred (loaded) into the process chamber 11 by the boat support table 17. The wafers 9 loaded into the process chamber 11 are then heated to a predetermined temperature by the heater 4. An apparatus provided with such a process furnace is may also be referred to as a “vertical type batch apparatus”. The wafers 9 accommodated in the process chamber 11 can be broadly classified into product wafers and side dummy wafers. Each of the product wafers is a wafer on which a semiconductor device such as an IC (integrated circuit) is actually manufactured. The product wafers are placed in a center portion (in the up-down direction) of an entire arrangement region of the wafers 9 arranged in the process chamber 11. On the other hand, the side dummy wafers are wafers used instead of the product wafers, and are placed in positions, among the entire arrangement region of the wafers 9 arranged in the process chamber 11, where a quality of the wafers serving as the product wafers cannot be ensured, for example, at both ends in the vertical direction. That is, the side dummy wafers are placed with a product region interposed therebetween. In the process chamber 11, a region in which the product wafers are placed may also be referred to as the “product region”, and a region in which the side dummy wafers are placed may also be referred to as a “dummy region”. Hereinafter, the side dummy wafers may also be referred to as “dummy wafers”.

As shown in FIG. 2, the supply buffer 8 is a region provided on the side wall of the cylinder of the inner tube 6 and protrudes outward from the side wall. The supply buffer 8 is divided into three portions 8a, 8b and 8c along a circumferential direction of the cylinder by partitions 89a and 89b. In addition, each of the divided portions 8a, 8b and 8c of the supply buffer 8 may be used as a nozzle chamber.

The first gas nozzle 22 and the second gas nozzle 23 through the first source gas is supplied are provided in a central portion 8b of the divided portions of the supply buffer 8. For example, a width of the central portion 8b is set to be within a range from 1 to 1.2 times a sum of lateral widths (major diameters described later) of the first gas nozzle 22 and the second gas nozzle 23. Thereby, it is possible to reduce a dead space in the central portion 8b, and it is also possible to suppress a backflow (also referred to as a “return flow”) of the first source gas. At a boundary between the central portion 8b of the supply buffer 8 and the cylinder, a sector (that is, a sector of a fan shape) is formed by a virtual arc connecting both circumferential ends of the cylinder, and a center C1 of the wafer 9. According to the present embodiments, a central angle of the sector is set to be less than 30°. In the present disclosure, the central angle of the sector can be set arbitrarily.

An ejection apparatus capable of ejecting the first source gas onto the wafers 9 is constituted by at least the first gas nozzle 22 and the second gas nozzle 23. The ejection apparatus may further include other gas nozzles 24 to 27, and may further include the nozzle supports 28 and 29. The ejection apparatus may further include the gas supply systems mentioned above.

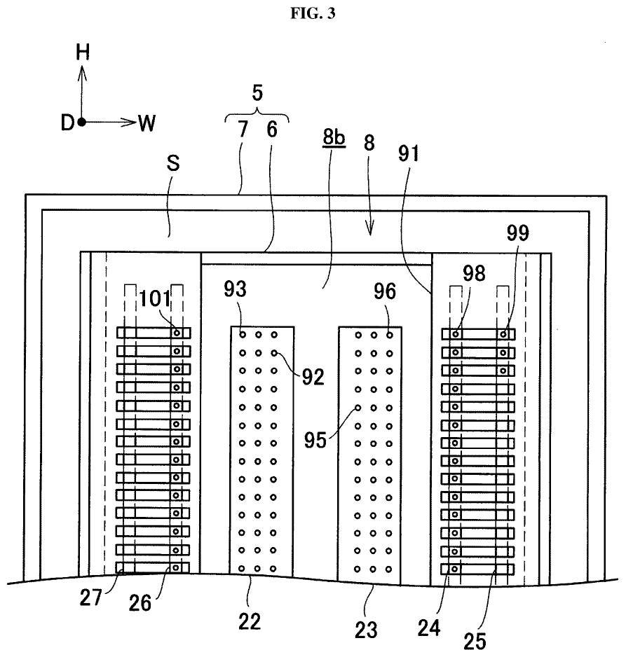

As shown in FIG. 3, a supply slit 91 is provided at the central portion 8b of the supply buffer 8. The supply slit 91 opens over an entirety of the central portion 8b in the up-down direction H of the apparatus and an entirety of the central portion 8b in the width direction W of the apparatus. As a result, the first gas nozzle 22 and the second gas nozzle 23 face the wafer 9 inside the cylinder throughout both in the up-down direction H of the apparatus and in the width direction W of the apparatus.

### <Exhaust Slits>

As shown in FIG. 2, a plurality of exhaust slits (which include the main exhaust slit 82 and the subsidiary exhaust slits 83a and 83b) are provided at the side wall of the cylinder. The exhaust slits are configured such that the source gas is exhausted from inside the cylinder. According to the present embodiments, the number of the exhaust slits is three (that is, one main exhaust slit 82 and two subsidiary exhaust slits 83a and 83b). In the present disclosure, the number of the exhaust slits may preferably be two or more.

### <Main Exhaust Slit>

The main exhaust slit 82 is provided at the side wall of the cylinder opposite to the supply buffer 8 with respect to the center C1 of the wafer 9.

### <Subsidiary Exhaust Slits>

The two subsidiary exhaust slits 83a and 83b are open on both sides of an imaginary vertical plane α set inside the cylinder. The imaginary vertical plane α is a plane perpendicular to the wafer 9. As shown in FIG. 2, the imaginary vertical plane α is set so as to, when viewed from above, pass through a circumferential center of the cylinder at a boundary between the supply buffer 8 and the cylinder and an axis of the cylinder (that is, the center C1 of the wafer 9). The axis of the cylinder overlaps with the center C1 of the wafer 9.

The two subsidiary exhaust slits 83a and 83b serving as a pair of exhaust slits are provided at the same height as the main exhaust slit 82 with the main exhaust slit 82 interposed therebetween. When viewed from above, imaginary lines L (which connect each of centers of the subsidiary exhaust slits 83a and 83b and the center C1 of the wafer 9) are set. According to the present embodiments, an angle between each of the imaginary lines L and the imaginary vertical plane α is an obtuse angle. Such an angle mentioned above is measured starting from the supply buffer 8. In the present disclosure, the angle between each of the imaginary lines L and the imaginary vertical plane α is not limited to an obtuse angle.

As shown in FIG. 2, a width of each of the two subsidiary exhaust slits 83a and 83b along the circumferential direction of the cylinder is smaller than a width of the main exhaust slit 82. However, in the present disclosure, the width of each of the subsidiary exhaust slits 83a and 83b may be greater than or equal to the width of the main exhaust slit 82.

According to the present embodiments, an opening width of the main exhaust slit 82 along the circumferential direction of the cylinder may be narrowed from an upper portion (top) to a lower portion (bottom) along the axial direction of the cylinder. Similarly, an opening width of each of the pair of subsidiary exhaust slits 83a and 83b along the circumferential direction of the cylinder may be narrowed from top to bottom along the axial direction of the cylindrical portion. In the present disclosure, the opening widths of each of the main exhaust slit 82 and the pair of subsidiary exhaust slits 83a and 83b along the circumferential direction of the cylinder may be set appropriately.

In addition, the subsidiary exhaust slits 83a and 83b are located opposite to the supply buffer 8 with an imaginary plane β interposed therebetween, and are configured such that the gas supplied from the supply buffer 8 is exhausted to an outside (outer portion) of the cylinder at a position farther than the imaginary plane β. Thereby, it is possible to sufficiently circulate (supply) the gas supplied into the process chamber 11 within the process chamber 11. In the present disclosure, the imaginary plane β is a plane perpendicular to the wafer 9. As shown in FIG. 2, the imaginary plane β is set to pass through the axis of the cylinder (the center C1 of the wafer 9) when viewed from above, and to separate the supply buffer 8 from the main exhaust slit 82 and the subsidiary exhaust slits 83a and 83b.

### <Main Configuration>

Subsequently, each of the gas nozzles in the substrate processing apparatus 1 according to the present embodiments will be described in detail. In addition, positions of the gas nozzles 22, 23, 24, 25, 26 and 27 in FIG. 3 are schematically illustrated for explanation, and may differ from the actual positions thereof inside the process chamber 11. In addition, in the following descriptions, the position of each of the gas nozzles when viewed from above may refer to a center position of each gas nozzle of a cylindrical shape.

In the supply buffer 8, the first gas nozzle 22 serving as a first ejector, the second gas nozzle 23 serving as a second ejector, the third gas nozzle 24 serving as a third ejector, the fourth gas nozzle 25 serving as a fourth ejector, the fifth gas nozzle 26 serving as a fifth ejector and the sixth gas nozzle 27 serving as a sixth ejector are arranged. In addition, the first gas nozzle 22 and the second gas nozzle 23 are arranged in the central portion 8b among the divided portions of the supply buffer 8, the third gas nozzle 24 and the fourth gas nozzle 25 are arranged in an upper portion 8a among the divided portions of the supply buffer 8 with respect to a paper plane in FIG. 2, and the fifth gas nozzle 26 and the sixth gas nozzle 27 are arranged in a lower portion 8c among the divided portions of the supply buffer 8 with respect to the paper plane in FIG. 2. In addition, the first gas nozzle 22 and the second gas nozzle 23 are configured to be symmetrical with each other with respect to the imaginary vertical plane α. Therefore, it is possible to uniformly (evenly) supply the first source gas to the process chamber 11 through the first gas nozzle 22 and the second gas nozzle 23.

### <First Ejector>

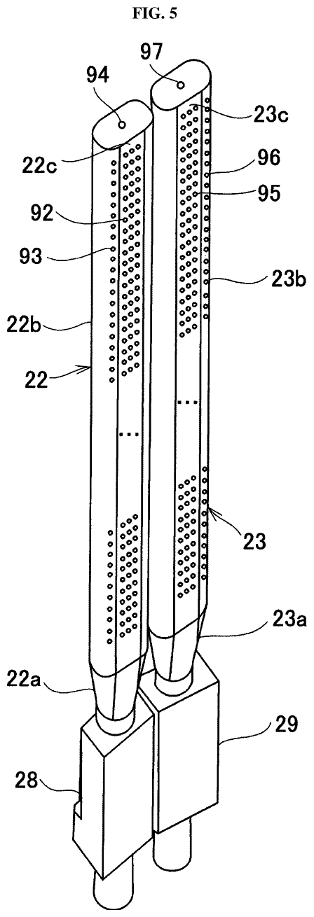

The first gas nozzle 22 extends in the up-down direction, and is disposed opposite the main exhaust slit 82 as shown in FIG. 2. In addition, as shown in FIG. 5, the first gas nozzle 22 is supported by the first nozzle support 28. For example, the first gas nozzle 22 is constituted by: a tapered structure (tapered portion) 22a whose cross-sectional area gradually increases from a lower portion (bottom) to an upper portion (top) thereof; and an ejection structure 22b whose cross-section is elliptical and extending upward from an upper end of the tapered structure 22a. A cross-sectional area of the ejection structure 22b is set to be uniform over an entire length thereof in the up-down direction.

A lower end of the tapered structure 22a is of a circular shape, and the upper end of the tapered structure 22a is of an elliptical shape similar to the ejection structure 22b. In addition, the ejection structure 22b is provided with: a flat surface 22c facing the wafer 9 parallel to a major axis direction and perpendicular to a minor axis direction; and two surfaces (that is, two semi-cylindrical surfaces) connected to both sides of the flat surface 22c. A length of the flat surface 22c in the major axis direction is longer than a diameter of the lower end of the tapered structure 22a, and a length (thickness) of the flat surface 22c in the minor axis direction is shorter than the diameter of the lower end of tapered structure 22a. In addition, a length (lateral width) of the flat surface 22c is longer than a length (thickness) of the ejection structure 22b in the minor axis direction.

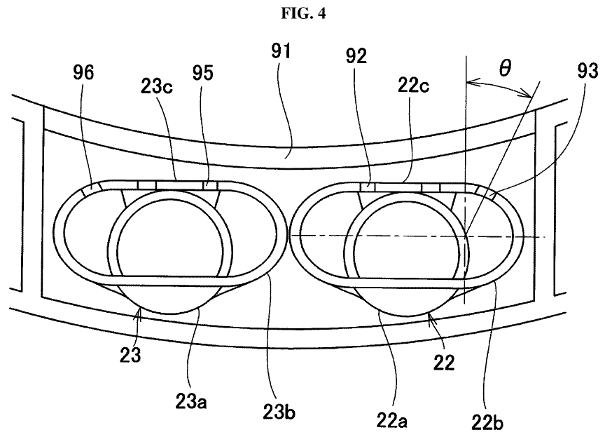

The flat surface 22c of the ejection structure 22b faces the main exhaust slit 82. In addition, an axis of the ejection structure 22b is eccentric toward the main exhaust slit 82 (that is, the center C1 of the wafer 9) relative to a center of the lower end of the tapered structure 22a. In other words, as shown in FIG. 4, the tapered structure 22a is provided such that the flat surface 22c of the ejection structure 22b protrudes toward the main exhaust slit 82 further than the lower end of the tapered structure 22a.

As shown in FIGS. 4 and 5, the ejection structure 22b is provided with: a plurality of first ejection holes 92 arranged on the flat surface 22c along a direction parallel to the substrate (that is, the wafer 9) and formed (provided) substantially perpendicular to the flat surface 22c; a plurality of second ejection holes 93 configured to open in a direction away from the second gas nozzle 23 on the semi-cylindrical surface opposite the second gas nozzle 23; and a third ejection hole 94 formed (provided) in a center of a top plate configured to close an upper end of the ejection structure 22b. Hereinafter, each of the first ejection holes 92 may also be referred to as a “first ejection hole 92”, and each of the second ejection holes 93 may also be referred to as a “second ejection hole 93”.

The first ejection holes 92 are arranged on the same plane, and the first ejection hole 92 is substantially perpendicular to the flat surface 22c. Therefore, it is possible to eject the gas in the same or substantially the same direction (that is, in the perpendicular direction or substantially perpendicular direction). In addition, at least one among the first ejection holes 92 directly faces (that is, provided directly opposite to) the main exhaust slit 82 via a central axis of the wafer 9. In the present disclosure, the term “substantially the same direction” may refer to a case where extension lines of ejection directions of the first ejection holes 92 are aligned to the extent that the extension lines do not intersect with one another within the process chamber 11.

The second ejection hole 93 is provided in one of the two surfaces connected to the flat surface 22c, and is configured to eject the gas in a direction inclined with respect to the ejection direction of the first ejection hole 92. An arrangement of the ejection holes including the first ejection holes 92 and the second ejection holes 93 is not mirror symmetric with one another. Therefore, the arrangement of the ejection holes is asymmetric with respect to an arbitrary plane perpendicular to the wafer 9. In addition, the first source gas is ejected from the first ejection holes 92 in a direction substantially perpendicular to the flat surface 22c, and the first source gas is ejected radially when viewed from above through the first ejection holes 92 and the second ejection holes 93.

Further, in the present disclosure, a size of an opening of the second ejection hole 93 is set so as not to generate a steady return flow which passes along an inner wall of the inner tube 6 through the imaginary plane β (directly facing the first ejection hole 92 on the central axis of the wafer 9) in a direction approaching the first ejection hole 92. For example, a diameter (hole diameter) of the second ejection hole 93 is set to be 1 mm to 4 mm. As a result, it is possible to suppress a generation of the steady return flow. In addition, the second ejection hole 93 is provided at a position that is separated horizontally by θ (for example, from 5° to 60°, preferably from 15° to) 45° from the direction perpendicular to the major axis of the ejection structure 22b (that is, a direction in which the first ejection hole 92 opens). In addition, a distance between adjacent ejection holes among the first ejection holes 92 is set to be smaller than a distance between the second ejection hole 93 and the first ejection hole 92 located closest to the second ejection hole 93.

In the present disclosure, the first ejection holes 92 and the second ejection holes 93 arranged horizontally are provided in a multistage manner at equal intervals along the up-down direction (vertical direction), and a height of each ejection hole 92 and 93 corresponds to each of the wafers 9 arranged in the multistage manner. In addition, in FIG. 4, two ejection holes are shown as the first ejection holes 92 provided in the flat surface 22c of the ejection structure 22b. However, the number of the first ejection holes 92 on the same stage may be three as shown in FIG. 5, or may be four or more. Such a configuration may also be applied for a plurality of first ejection holes 95 and a plurality of second ejection holes 96 of the second gas nozzle 23 described below.

### <Second Ejector>

A shape of the second gas nozzle 23 is substantially the same as the first gas nozzle 22. The second gas nozzle 23 is supported by the second nozzle support 29. For example, the second gas nozzle 23 is constituted by: a tapered structure (tapered portion) 23a whose cross-sectional area gradually increases from a lower portion (bottom) to an upper portion (top) thereof; and an ejection structure 23b whose cross-section is elliptical. In addition, the ejection structure 23b is provided with: a flat surface 23c extending upward from an upper end of the tapered structure 23a; and two surfaces (that is, two semi-cylindrical surfaces) connected to both sides of the flat surface 23c. In addition, a length (lateral width) of the flat surface 23c is longer than a length (thickness) of the ejection structure 23b in a minor axis direction.

The flat surface 23c of the ejection structure 23b faces the main exhaust slit 82. The ejection structure 23b is provided with: the plurality of first ejection holes 95 arranged on the flat surface 23c along the direction parallel to the substrate (that is, the wafer 9) and formed (provided) substantially perpendicular to the flat surface 23c; the plurality of second ejection holes 96 configured to open in a direction away from the first gas nozzle 22 in the semi-cylindrical surface opposite the first gas nozzle 22; and a third ejection hole 97 formed (provided) in a center of a top plate configured to close an upper end of the ejection structure 23b. Hereinafter, each of the first ejection holes 95 may also be referred to as a “first ejection hole 95”, and each of the second ejection holes 96 may also be referred to as a “second ejection hole 96”.

The first ejection holes 95 are arranged on the same plane, and the first ejection hole 95 is substantially perpendicular to the flat surface 23c. Therefore, it is possible to eject the gas in the same or substantially the same direction (that is, in the perpendicular direction or substantially perpendicular direction). In addition, at least one among the first ejection holes 95 directly faces (that is, provided directly opposite to) the main exhaust slit 82 via the central axis of the wafer 9. In the present disclosure, the term “substantially the same direction” may refer to a case where extension lines of ejection directions of the first ejection holes 95 are aligned to the extent that the extension lines do not intersect with one another within the process chamber 11.

The second ejection hole 96 is provided in one of the two surfaces connected to the flat surface 23c, and is configured to eject the gas in a direction inclined with respect to the ejection direction of the first ejection hole 95. An arrangement of the ejection holes including the first ejection holes 95 and the second ejection holes 96 is asymmetric with respect to an arbitrary plane perpendicular to the wafer 9. In addition, the first source gas is ejected from the first ejection holes 95 in a direction substantially perpendicular to the flat surface 23c, and the first source gas is ejected radially when viewed from above through the first ejection holes 95 and the second ejection holes 96.

Further, in the present disclosure, a size of an opening of the second ejection hole 96 is set so as not to generate a steady return flow which passes along the inner wall of the inner tube 6 through the imaginary plane β (directly facing the first ejection hole 95 on the central axis of the wafer 9) in a direction approaching the first ejection hole 95. For example, a diameter (hole diameter) of the second ejection hole 96 is set to be 1 mm to 4 mm. As a result, it is possible to suppress a generation of the steady return flow. In addition, the second ejection hole 96 is provided at a position that is separated horizontally by an angle (for example, from 5° to 60°, preferably from 15° to) 45° from a direction perpendicular to a major axis of the ejection structure 23b (that is, a direction in which the first ejection hole 95 opens). In addition, a distance between adjacent ejection holes among the first ejection holes 95 is set to be smaller than a distance between the second ejection hole 96 and the first ejection hole 95 located closest to the second ejection hole 96.

As described above, in the present disclosure, the second ejection hole 93 of the first gas nozzle 22 and the second ejection hole 96 of the second gas nozzle 23 are configured to eject the first source gas in the directions away from each other. In addition, in the present disclosure, each of the first gas nozzle 22 and the second gas nozzle 23 is of an elliptical cylinder shape (in which the two surfaces connecting to the flat surface are the semi-cylindrical surfaces). However, the first gas nozzle 22 and the second gas nozzle 23 are not limited thereto. For example, the first gas nozzle 22 and the second gas nozzle 23 may be of a semi-elliptical cylinder shape (which is of a “kamaboko” shape) provided with two ¼ cylindrical surfaces connected to a flat surface thereof. In addition, the semi-elliptical cylinder shape may include a shape such as a rounded rectangular cylinder shape and a super elliptical cylinder shape.

### <Third Ejector>

The third gas nozzle 24 is provided with a plurality of ejection holes 98 facing at least the product region of the process chamber 11. The third gas nozzle 24 is configured such that the second source gas is supplied to the product wafers and the dummy wafers through the ejection holes 98. For example, the ejection holes 98 may be provided in both the product region and the dummy region, or may be provided in the product region alone.

### <Fourth Ejector>

The fourth gas nozzle 25 is provided with one or more ejection holes 99 through which the assist gas is supplied only to the substrates (wafers 9) in the upper dummy region (that is, an upper portion of the dummy region) of the dummy region. The number of the one or more ejection holes 99 at the fourth gas nozzle 25 is one or more. In other words, the fourth gas nozzle 25 is configured such that the assist gas is supplied to one or more stages of the dummy wafers. While the present embodiments will be described by way of an example in which the number of the one or more ejection holes 99 at the fourth gas nozzle 25 is three, the present embodiments are not limited thereto. For example, in the present disclosure, the number of the one or more ejection holes 99 may be set appropriately to one or more.

In addition, while the present embodiments will be described by way of an example in which the one or more ejection holes 99 are provided in the upper dummy region alone, the present embodiments are not limited thereto. For example, the one or more ejection holes 99 may be provided in both of the product region and the dummy region. In such a case, the number of the one or more ejection holes 99 arranged in one stage may be changed. For example, the number of the one or more ejection holes 99 arranged in the dummy region may be set to be greater than the number of the one or more ejection holes 99 arranged in the product region (or the number of the one or more ejection holes 99 arranged in one stage in the dummy region may be set to three and the number of the one or more ejection holes 99 arranged in one stage in the product region may be set to one) such that the assist gas is ejected more into the dummy region than into the product region.

### <Fifth Ejector>

The fifth gas nozzle 26 is provided with one or more ejection holes 101 facing the product region of the process chamber 11. The fifth gas nozzle 26 is configured such that the second source gas is supplied to the product wafers and the dummy wafers through the one or more ejection holes 101. In addition, the one or more ejection holes 101 may be provided in both of the product region and the dummy region, or may be provided in the product region alone.

### <Sixth Ejector>

The sixth gas nozzle 27 is provided with one or more ejection holes (not shown) facing the product region of the process chamber 11. The one or more ejection holes of the sixth gas nozzle 27 may be provided in both of the product region and the dummy region, or may be provided in the product region alone.

The sixth gas nozzle 27 is configured such that the assist gas is supplied to the product wafers through the one or more ejection holes of the sixth gas nozzle 27. By using the sixth gas nozzle 27, it is possible to adjust a uniformity on surfaces of the entire product wafers.

In addition, the assist gas is supplied through the fourth gas nozzle 25 and the sixth gas nozzle 27 when the first source gas is being supplied through the first gas nozzle 22 and the second gas nozzle 23, when the second source gas is being supplied through the third gas nozzle 24 and the fifth gas nozzle 26, or when both the first source gas and the second source gas are being supplied.

In addition, according to the present embodiments, the fourth gas nozzle 25 and the sixth gas nozzle 27 are arranged such that the first gas nozzle 22, the second gas nozzle 23, the third gas nozzle 24 and the fifth gas nozzle 26 are interposed therebetween. Further, the assist gas is supplied through the sixth gas nozzle 27 when the first source gas is being supplied through the first gas nozzle 22 and the second gas nozzle 23. The first source gas serves as a source gas of a Group 14 element. For example, as the source gas of the Group 14 element, a gas containing an element such as carbon (C), silicon (Si), germanium (Ge), tin (Sn) and lead (Pb) may be used. In addition, in the present disclosure, the first source gas may be a source gas containing an element other than the Group 14 element.

### <Controller>

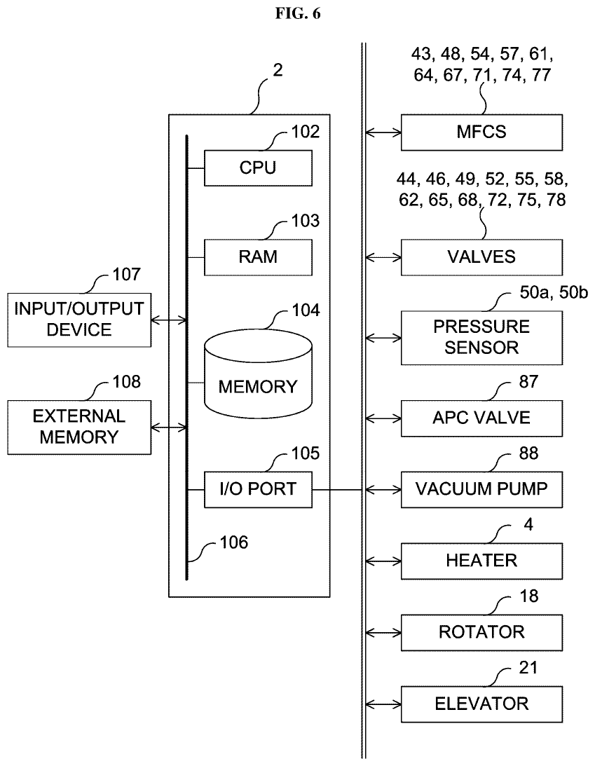

FIG. 6 is a block diagram schematically illustrating the substrate processing apparatus 1, and the controller (which is a control structure) 2 of the substrate processing apparatus 1 may be embodied by a computer. The computer includes a CPU (Central Processing Unit) 102, a RAM (Random Access Memory) 103, a memory 104 and an I/O port (input/output port) 105.

The RAM 103, the memory 104 and the I/O port 105 are configured to exchange data with the CPU 102 through an internal bus 106. For example, an input/output device 107 configured by, for example, a touch panel may be connected to the controller 2.

For example, the memory 104 is configured by a component such as a flash memory and a hard disk drive (HDD). For example, a control program configured to control operations of the substrate processing apparatus 1 or a process recipe containing information on procedures and conditions of a substrate processing described later may be readably stored in the memory 104.

The process recipe is obtained by combining steps (procedures) of the substrate processing described later such that the controller 2 can execute the steps by using the substrate processing apparatus 1 to acquire a predetermined result, and functions as a program. Hereinafter, the process recipe and the control program may be collectively or individually referred to as a “program”.

Thus, in the present specification, the term “program” may refer to the process recipe alone, may refer to the control program alone, or may refer to both of the process recipe and the control program. The RAM 103 functions as a memory area (work area) where a program or data read by the CPU 102 is temporarily stored.

The I/O port 105 is connected to components mentioned above such as the MFCs 43, 48, 54, 57, 61, 64, 67, 71, 74 and 77, the valves 44, 46, 49, 52, 55, 58, 62, 65, 68, 72, 75 and 78, the pressure sensors 50a and 50b, the APC valve 87, the vacuum pump 88, the heater 4, the temperature sensor, the rotator 18 and the elevator 21.

The CPU 102 is configured to read and execute the control program stored in the memory 104, and to read the process recipe stored in the memory 104 in accordance with an instruction such as an operation command inputted via the input/output device 107.

For example, in accordance with contents of the process recipe read from the memory 104, the CPU 102 is configured to be capable of controlling various operations such as flow rate adjusting operations for various gases by the MFCs 43, 48, 54, 57, 61, 64, 67, 71, 74 and 77, opening and closing operations of the valves 44, 46, 49, 52, 55, 58, 62, 65, 68, 72, 75 and 78 and an opening and closing operation of the APC valve 87. In addition, the CPU 102 is configured to be capable of controlling various operations such as a pressure adjusting operation by the APC valve 87 based on the pressure sensors 50a and 50b, a start and stop of the vacuum pump 88 and a temperature adjusting operation by the heater 4 based on the temperature sensor. In addition, the CPU 102 is configured to be capable of controlling various operations such as an operation of adjusting a rotation and a rotation speed of the boat 12 by the rotator 18 and an elevating and lowering operation of the boat 12 by the elevator 21.

For example, the controller 2 is not limited to a dedicated computer, and may be embodied by a general-purpose computer. For example, the controller 2 according to the present embodiments may be embodied by preparing an external memory 108 storing the program and by installing the program onto the general-purpose computer using the external memory 108. For example, the external memory 108 may include a magnetic disk such as a hard disk, an optical disk such as a CD, a magneto-optical disk such as an MO and a semiconductor memory such as a USB memory.

### <Substrate Processing Method>

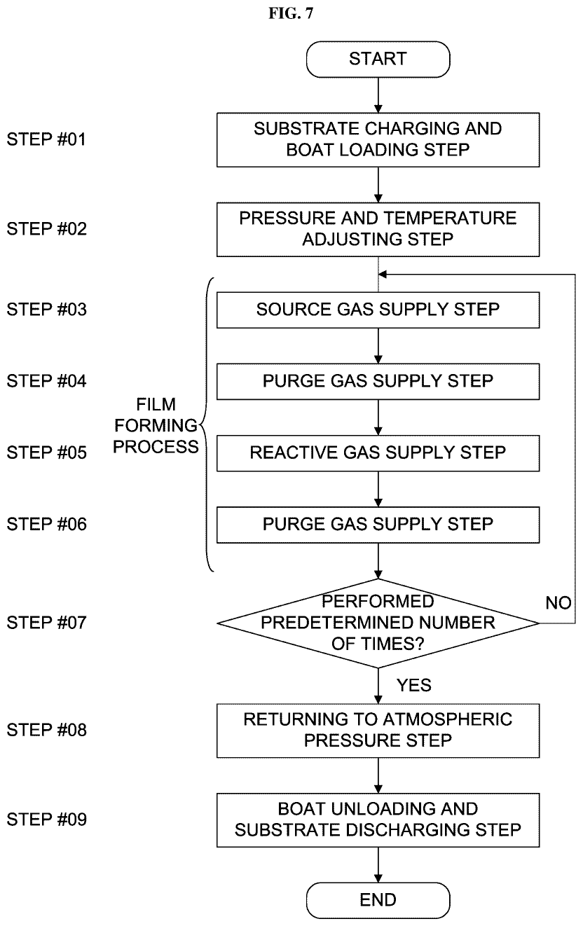

Subsequently, an example of the substrate processing will be described with reference to FIG. 7. Hereinafter, as an example of a manufacturing process of a semiconductor device, a cycle process of performing a film processing by alternately supplying a source (source material) serving as the first source gas and a reactant (reactive gas) serving as the second source gas to the process chamber 11 will be described. According to the present embodiments, an example of forming a silicon nitride film (Si₃N₄ film, hereinafter also referred to as a “SiN film”) on the substrate will be described. The SiN film is formed by using a silicon source gas serving as an example of the source and a nitrogen-containing gas serving as the reactant.

In the film forming process according to the present embodiments, the SiN film is formed on the wafer 9 by performing a cycle a predetermined number of times (once or more times). For example, the cycle includes: a step of supplying the source gas (first source gas) to the wafer 9 in the inner tube 6 (film forming step #1: STEP #03 in FIG. 7); a step of purging the source gas remaining in the inner tube 6 from the inner tube 6 (film forming step #2: STEP #04 in FIG. 7); a step of supplying the nitrogen-containing gas serving as the reactive gas (second source gas) to the wafer 9 in the inner tube 6 (film forming step #3: STEP #05 in FIG. 7); and a step of purging the nitrogen-containing gas remaining in the inner tube 6 from the inner tube 6 (film forming step #4: STEP #06 in FIG. 7). The steps in the cycle are performed non-simultaneously.

First, in STEP #01 in FIG. 7, the wafers 9 are loaded into the boat 12. By transferring (loading) the boat 12 into the inner tube 6, the wafers 9 in the boat 12 are accommodated in the cylinder of the inner tube 6. Subsequently, in STEP #02 in FIG. 7, after the boat 12 is loaded into the inner tube 6, a pressure (inner pressure) and a temperature (inner temperature) of the inner tube 6 are adjusted. Subsequently, the four steps of the film forming step (that is, the film forming step #1 to the film forming step #4) are performed sequentially. Hereinafter, each of the four steps of the film forming step is described in detail.

### <Film Forming Step #1>

In the film forming step #1 (that is, in STEP #03 in FIG. 7), for example, a flash supply of the first source gas is performed in a manner mentioned above. For example, with the valve 44 open and the valve 46 closed, the first source gas supplied from the source gas supply source 42 by the MFC 43 is supplied to the tank 45. Similarly, with the valve 49 open and the valve 52 closed, the first source gas supplied from the source gas supply source 47 by the MFC 48 is supplied to the tank 51. In the present step, an accumulation time and a flow rate of the first source gas supplied to each of the tanks 45 and 51 are set such that an amount of the first source gas supplied to each of the tanks 45 and 51 is equal to or greater than a minimum amount at which the flash supply can be performed with respect to the tanks 45 and 51, and such that the same amount of the first source gas can be accumulated in the tanks 45 and 51.

When a predetermined amount of the first source gas is accumulated in each of the tank 45 and the tank 51, the valve 44 is closed and the valve 46 is opened to release the first source gas from the tank 45. Thereby, the flash supply of the first source gas to the first gas nozzle 22 is performed. Simultaneously, the valve 49 is closed and the valve 52 is opened to release the first source gas from the tank 51. Thereby, the flash supply of the first source gas to the second gas nozzle 23 is performed. In other words, the first gas nozzle 22 and the second gas nozzle 23 are configured to eject the same gas at substantially the same flow rate at the same time (that is, simultaneously). Therefore, it is possible to supply a large amount of the first source gas into the process chamber 11 without increasing a pressure (inner pressure) of the first gas nozzle 22 and a pressure (inner pressure) of the second gas nozzle 23.

When the first source gas is supplied, the first source gas is simultaneously ejected from the first gas nozzle 22 and the second gas nozzle 23 toward the wafers 9, and the first source gas ejected as described above is exhausted to the outside of the cylinder through the main exhaust slit 82 and the two subsidiary exhaust slits 83a and 83b.

In addition, the flow rate (substantially the same flow rate) of the first source gas supplied through each of the first gas nozzle 22 and the second gas nozzle 23 is a flow rate that generates an unsteady return flow which passes through the imaginary plane β directly facing the first ejection holes 92 and the first ejection holes 95 on the central axis of the wafer 9, excluding the vicinity of the inner wall of the inner tube 6, in the direction approaching the first ejection holes 92 and the first ejection holes 95. Thereby, it is possible to suppress the generation of the steady return flow. In addition, in the film forming step #1, the inert gas from the inert gas supply sources 66 and 69 may be used as the carrier gas.

For example, as the first source gas supplied through the gas supply pipe 31 and the gas supply pipe 32, the silicon source gas mentioned above may be used. For example, as the first source gas, a gas containing silicon and halogen may be used. For example, as the gas containing silicon and halogen, an inorganic chlorosilane-based gas such as tetrachlorosilane (SiCl₄, abbreviated as STC) gas, hexachlorodisilane (Si₂Cl₆, abbreviated as HCDS) gas and octachlorotrisilane (Si₃Cl₈, abbreviated as OCTS) gas may be used. For example, as the gas containing silicon and halogen, one or more of the gases mentioned above may be used. The first source gas corresponds to a first source material of the present disclosure. In addition, in the present disclosure, the first source material is not limited to a gaseous substance. For example, the first source material may be a liquid substance such as a mist substance.

Additionally, the assist gas such as N₂ is ejected toward the wafer 9 using the fourth gas nozzle 25 and the sixth gas nozzle 27. That is, according to the present embodiments, the assist gas is supplied through the fourth gas nozzle 25 and the sixth gas nozzle 27 when the first source gas is supplied through the first gas nozzle 22 and the second gas nozzle 23.

### <Film Forming Step #2>

In the film forming step #2, the valves 46 and 52 are closed to stop a supply of the first source gas, and the valves 68 and 72 are opened to supply the inert gas (purge gas) from the inert gas supply sources 66 and 69 to the first gas nozzle 22 and the second gas nozzle 23. In addition, for example, by controlling an exhaust pump such as the vacuum pump 88 and the APC valve 87, the reaction tube 5 is exhausted such that a pressure (inner pressure) of the reaction tube 5 can be adjusted (or set) to a predetermined pressure (that is, a vacuum degree), for example, 20 Pa or less, and such that the first source gas remaining in the inner tube 6 can be removed from the inner tube 6. In the present step, the assist gas is continuously supplied through the fourth gas nozzle 25 and the sixth gas nozzle 27. Thereby, it is possible to further improve an effect of purging the first source gas remaining in the inner tube 6.

### <Film Forming Step #3>

In the film forming step #3, the nitrogen-containing gas serving as the second source gas is supplied. With the valve 55 open, the second source gas supplied from the source gas supply source 53 and whose flow rate is adjusted by the MFC 54 is supplied into the inner tube 6 (that is, the cylinder) through the third gas nozzle 24. Similarly, with the valve 62 open, the second source gas from the source gas supply source 59 and whose flow rate is adjusted by the MFC 61 is supplied into the inner tube 6 through the fifth gas nozzle 26. The second source gas supplied through the third gas nozzle 24 and the fifth gas nozzle 26 is exhausted to an outside (outer portion) of the inner tube 6 through the main exhaust slit 82 and the subsidiary exhaust slits 83a and 83b. By supplying the second source gas, a silicon-containing film on a base film (underlying film) of the wafer 9 reacts with the second source gas. Thereby, it is possible to form the SiN film on the wafer 9.

According to the present embodiments, for example, as the second source gas, a gas such as ammonia (NH₃) gas may be used. That is, the NH₃ gas is supplied into the inner tube 6 while being exhausted through the plurality of exhaust slits. By supplying the NH₃ gas, the silicon-containing film on the base film (underlying film) of the wafer 9 reacts with the NH₃ gas. Thereby, it is possible to form the SiN film on the wafer 9. The second source gas corresponds to a second source material of the present disclosure. In addition, in the present disclosure, the second source material is not limited to a gaseous substance. For example, the second source material may be a liquid substance such as a mist substance.

Additionally, in the film forming step #3, the assist gas is continuously supplied through the fourth gas nozzle 25 and the sixth gas nozzle 27. That is, according to the present embodiments, the assist gas is supplied through the fourth gas nozzle 25 and the sixth gas nozzle 27 when the second source gas is supplied through the third gas nozzle 24 and the fifth gas nozzle 26.

### <Film Forming Step #4>

In the film forming step #4, the valves 55 and 62 are closed to stop a supply of the second source gas, and the valves 75 and 78 are opened to supply the inert gas (purge gas) from the inert gas supply sources 73 and 76 to the third gas nozzle 24 and the fifth gas nozzle 26. In addition, for example, by controlling the exhaust pump such as the vacuum pump 88 and the APC valve 87, the reaction tube 5 is exhausted such that the pressure (inner pressure) of the reaction tube 5 can be adjusted (or set) to the predetermined pressure (that is, the vacuum degree), for example, 20 Pa or less, and such that the second source gas remaining in the inner tube 6 can be removed from the inner tube 6. In the present step, the assist gas is continuously supplied through the fourth gas nozzle 25 and the sixth gas nozzle 27. Thereby, it is possible to further improve an effect of purging the second source gas remaining in the inner tube 6.

According to the present embodiments, the cycle includes the film forming steps #1 to #4 mentioned above. In STEP #07 in FIG. 7, by determining whether the cycle including the film forming steps #1 to #4 is performed the predetermined number of times, it is possible to form the SiN film of a predetermined thickness on the wafer 9. According to the present embodiments, the cycle including the film forming steps #1 to #4 is repeatedly performed a plurality number of times. However, in the present disclosure, the cycle including the film forming steps #1 to #4 may be performed once without being repeatedly performed.

After the film forming process mentioned above is completed (that is, the cycle including the film forming steps #1 to #4 is performed the predetermined number of times), in STEP #08 in FIG. 7, the inner pressure of the inner tube 6 is returned to a normal pressure (that is, the atmospheric pressure). For example, the inert gas such as the N₂ gas is supplied into the inner tube 6 and then exhausted. Thereby, an inside (inner portion) of the inner tube 6 is purged with the inert gas, and a substance such as the gas remaining in the inner tube 6 is removed from the inner tube 6 (purge by the inert gas). Thereafter, an atmosphere (inner atmosphere) of the inner tube 6 is replaced with the inert gas (substitution by the inert gas), and the inner pressure of the inner tube 6 is returned to the normal pressure.

Then, in STEP #09 in FIG. 7, the wafer 9 is removed from the inner tube 6. Thereby, the substrate processing according to the present embodiments is completed. A method of manufacturing a semiconductor device according to the present embodiments may be constituted by the steps mentioned above.

### Analysis Example

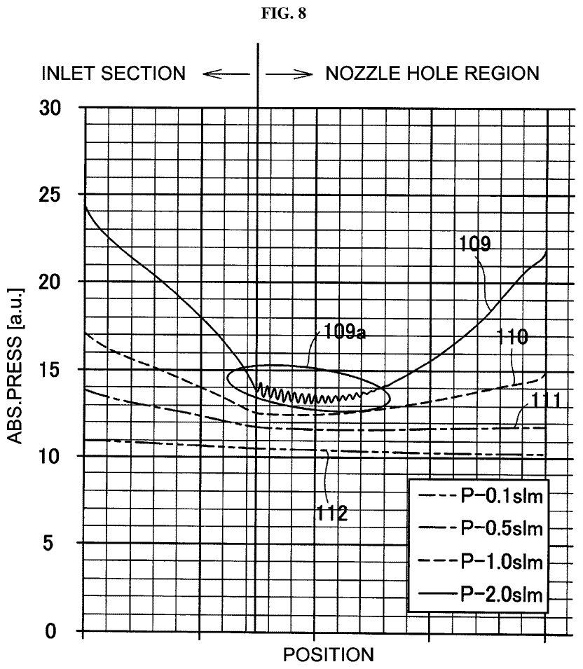

Subsequently, a relationship between the flow rate of the first source gas and each of the inner pressures of the first gas nozzle 22 and the second gas nozzle 23, which are obtained by the substrate processing method performed by using the substrate processing apparatus 1 of the present embodiments, will be described. FIG. 8 is a diagram (graphs) schematically illustrating a relationship between a position in the first gas nozzle 22 and the inner pressure of the first gas nozzle 22. Configurations of the first gas nozzle 22 and the second gas nozzle 23 are substantially the same. Thus, in the following, the relationship related to the first gas nozzle 22 will be described and a detailed description of the relationship related to the second gas nozzle 23 will be omitted.

In FIG. 8, the “INLET SECTION” indicates the tapered structure 22a, and the “NOZZLE HOLE REGION” indicates the ejection structure 22b. In addition, in FIG. 8, a solid line 109 indicates a case where the flow rate of the first source gas is set to be 2.0 slm, a dashed line 110 indicates a case where the flow rate of the first source gas is set to be 1.0 slm, a dash-single dotted line 111 indicates a case where the flow rate of the first source gas is set to be 0.5 slm, and a dash-double dotted line 112 indicates a case where the flow rate of the first source gas is set to be 0.1 slm.

When the first source gas is supplied, the first source gas flows upward from the lower end of the tapered structure 22a. As described above, the cross-sectional area of the tapered structure 22a gradually increases from the lower portion toward the upper portion thereof. Therefore, a pressure of the first source gas decreases as the first source gas flows upward in the tapered structure 22a.

The first source gas that flows into the ejection structure 22b flows upward within the ejection structure 22b while being ejected into the inner tube 6 through the first ejection holes 92 and the second ejection holes 93 of each stage, and the first source gas that is not ejected through the first ejection holes 92 and the second ejection holes 93 is released into the inner tube 6 through the third ejection hole 94.

As shown in FIG. 8, the greater the flow rate of the first source gas, the higher the energy (that is, kinetic, positional, pressure or internal energy) of the first source gas serving as a fluid. In addition, the pressure thereof increases quadratically toward the upper end (front end or tip) of the ejection structure 22b. In such a case, the flow rate of the first source gas through the first ejection holes 92 and the second ejection holes 93 at an upper stage (upper end) is greater than the flow rate of the first source gas ejected through the first ejection holes 92 and the second ejection holes 93 at a lower stage (lower end). That is, a difference in the flow rate of the first source gas may occur between an upper portion (front end) and a lower portion (base) of the ejection structure 22b. In addition, when the flow rate of the first source gas is increased (for example, when the flow rate is set to 2.0 slm), an oscillatory flow 109a may also occur at the lower portion of the ejection structure 22b.

On the other hand, when the flow rate of the first source gas is set to an appropriate flow rate for the first gas nozzle 22 (for example, a flow rate of 0.1 slm), it is possible to reduce a difference in a pressure (inner pressure) between the upper stage and lower stage of the ejection structure 22b. In other words, by adjusting the flow rate of the first source gas and the cross-sectional area of the ejection structure 22b of the first gas nozzle 22, it is possible to suppress an increase in the inner pressure at the front end (tip) of the ejection structure 22b. Thereby, it is possible to prevent an asymmetric flow of the first source gas.

According to the present embodiments, the cross-sectional areas of the ejection structure 22b of the first gas nozzle 22 and the ejection structure 23b of the second gas nozzle 23 are set such that the flow rate of the first source gas is lower than or equal to a predetermined flow rate at which a quadratic increase of the inner pressure of the ejection structure 22b of the first gas nozzle 22 (or the ejection structure 23b of the second gas nozzle 23) from the lower stage toward the upper stage of the first ejection holes 92 (first ejection holes 95) is prevented.

Subsequently, results of measuring a pressure distribution and a flow velocity distribution in a horizontal plane at a specified height of the first gas nozzle 22 (or the second gas nozzle 23) will be described as an analysis example. The results are obtained by the substrate processing method performed using the substrate processing apparatus 1 of the present embodiments. The results will be described together with results of a comparative example. A substrate processing apparatus of the comparative example differs from the substrate processing apparatus 1 of the present embodiments in that the second ejection holes 93 (the second ejection holes 96) are not provided. A configuration of the substrate processing apparatus of the comparative example, other than the second ejection holes 93, is substantially the same as that of the substrate processing apparatus 1 of the present embodiments.

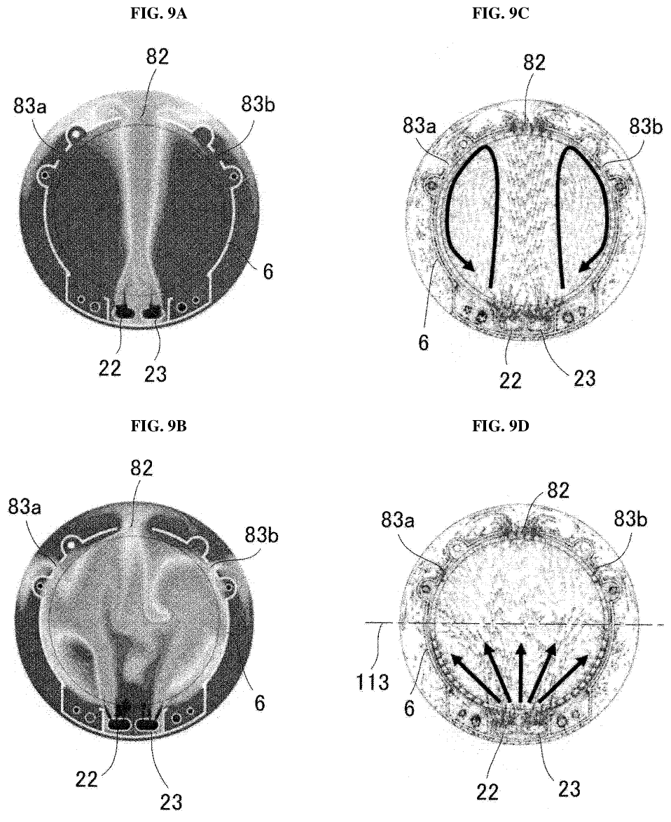

FIG. 9A is a diagram schematically illustrating a pressure distribution of a decomposition product of the source gas related to the first gas nozzle 22 (or the second gas nozzle 23) when the second ejection hole 93 is not provided (that is, when the first ejection hole 92 alone is provided on the flat surface 22c of the ejection structure 22b), FIG. 9B is a diagram schematically illustrating the pressure distribution of the decomposition product of the source gas related to the first gas nozzle 22 (or the second gas nozzle 23) when the second ejection hole 93 is provided, FIG. 9C is a diagram schematically illustrating a flow velocity distribution related to the first gas nozzle 22 (or the second gas nozzle 23) when the second ejection hole 93 is not provided, and FIG. 9D is a diagram schematically illustrating the flow velocity distribution related to the first gas nozzle 22 (or the second gas nozzle 23) when the second ejection hole 93 is provided

As shown in FIG. 9A, in the comparative example, an entirety of the first ejection holes 92 eject the gas in the same or substantially the same direction. Thus, a narrow gas flow path (also referred to as a “main flow path” or a “primary flow path”) is formed and the gas is exhausted through the main exhaust slit 82 without diffusing inside the inner tube 6. Therefore, as shown in FIG. 9C, a backflow occurs inside the inner tube 6 and outside of the main flow path. Thereby, the gas may stagnate inside the inner tube 6 and outside of the main flow path. As a result, a high resolution and high partial pressure state may occur outside the main flow path, and a uniformity on the surface of the wafer 9 may decrease.

On the other hand, as shown in FIG. 9B, according to the present embodiments, the second ejection hole 93 is provided to eject the gas in the direction inclined with respect to a flow of the gas ejected through the first ejection holes 92. Therefore, a width of a flow path of the gas flowing in the inner tube 6 is widened such that the gas diffuses in the inner tube 6 and is exhausted not only through the main exhaust slit 82 but also through the subsidiary exhaust slits 83a and 83b. As a result, as shown in FIG. 9D, the return flow of the gas is reduced, and the stagnation of the gas in the inner tube 6 is also reduced. From FIG. 9D, it can be seen that no return flow (which passes through an imaginary plane 113 perpendicular to a line connecting a center of the ejection apparatus and a center of the main exhaust slit 82 on a central axis of the substrate (that is, the wafer 9) in a direction approaching the ejection apparatus) is generated. Therefore, it is possible to improve a partial pressure height in the inner tube 6, and it is also possible to improve the uniformity on the surface of the wafer 9. Although the flow becomes asymmetric between left and right and fluctuates (oscillates), such an effect is limited. In addition, such an effect can be further suppressed by optimizing shapes of the first gas nozzle 22 and the second gas nozzle 23, in particular, the number, positions and an orientation of each of the first ejection holes 92 and the second ejection holes 93.

### Functions and Effects

According to the present embodiments, it is possible to obtain one or more of the effects described below.

According to the present embodiments, the first gas nozzle 22 and the second gas nozzle 23 are respectively provided with three or more ejection holes arranged along a direction substantially parallel to the surface of the substrate (the wafer 9), that is, the first ejection holes 92 and 95 and the second ejection holes 93 and 96 configured to eject the gas in a direction different from the ejection direction of the first ejection holes 92 and 95. In addition, the first gas nozzle 22 and the second gas nozzle 23 are configured such that the gas is supplied into the inner tube 6 (that is, the process chamber 11) through the first ejection holes 92 and 95 and the second ejection holes 93 and 96. Therefore, the gas flow in the inner tube 6 becomes wider and the backflow is suppressed. In addition, since the stagnation of the gas in the inner tube 6 is suppressed, it is possible to improve a supply efficiency of the source gas, and it is also possible to improve the gas replacement. Therefore, it is possible to improve the partial pressure height in the inner tube 6. In addition, it is possible to improve the uniformity on the surface of the wafer 9 in the film forming process, and it is also possible to perform the film forming process on side surfaces of a fine hole or a groove.

In addition, the first gas nozzle 22 and the second gas nozzle 23 are of an elliptical cylinder shape with the flat surface 22c. Further, the first ejection holes 92 and 95 are provided on the flat surface 22c such that the ejection directions are the same or substantially the same. As a result, the gases ejected through the first ejection holes 92 and 95 can be prevented from joining together and strengthening each other. Thereby, it is possible to uniformize the flow rate of the gas inside the inner tube 6.

In addition, each of the first ejection holes 92 and each of the first ejection holes 95 provided in the first gas nozzle 22 and the second gas nozzle 23, respectively, are configured to eject the gas in the same or substantially the same direction. Therefore, even when there is variation in a hole diameter of each of the first ejection holes 92 and each of the first ejection holes 95, it is possible to suppress an effect on the flow velocity distribution, and it is also possible to improve a uniformity between the wafers 9.

In addition, the first gas nozzle 22 and the second gas nozzle 23 are constituted by the tapered structures 22a and 23a and the ejection structures 22b and 23b, respectively, and the tapered structures 22a and 23a are configured such that the cross-sectional areas gradually increase upward. In other words, flow path areas of the first gas nozzle 22 and the second gas nozzle 23 at upper ends (front ends) thereof are larger than at lower ends (base ends) thereof. Thereby, it is possible to suppress an increase in the pressure (inner pressure) at the front end of each of the first gas nozzle 22 and the second gas nozzle 23.

In addition, the first ejection holes 92 and 95 and the second ejection holes 93 and 96 are provided on the same plane, and the heights of the first ejection holes 92 and 95 and the heights the second ejection holes 93 and 96 correspond to each of the wafers 9 arranged in the multistage manner. Therefore, it is possible to widen (or expand) and to uniformize the flow of the gas supplied to each of the wafers 9. Thereby, it is possible to improve the uniformity on the surface of the wafer 9 and the uniformity between the wafers 9. In addition, at least one among the first ejection holes 92 and 95 directly faces (that is, provided directly opposite to) the main exhaust slit 82. Thereby, it is possible to promote an exhaust of the first source gas within the process chamber 11, and it is possible to suppress the stagnation of the first source gas.

In addition, according to the present embodiments, the fourth gas nozzle 25 and the sixth gas nozzle 27 through which the assist gas is supplied are arranged such that the first gas nozzle 22, the second gas nozzle 23, the third gas nozzle 24 and the fifth gas nozzle 26 are interposed therebetween. Therefore, it is possible to dilute the first source gas and the second source gas by the assist gas supplied through the fourth gas nozzle 25 and the sixth gas nozzle 27. As a result, it is possible to improve the supply efficiency of the source gas. Further, it is possible to improve the gas replacement during the film forming process by using the fourth gas nozzle 25 and the sixth gas nozzle 27, and it is also possible to suppress the backflow, that is, the return flow of the gas leaving the supply buffer 8 and coming back to the supply buffer 8 due to a phenomenon such as eddies and a turbulence in the process chamber 11.

In addition, according to the present embodiments, the assist gas is supplied through the fourth gas nozzle 25 and the sixth gas nozzle 27 when the first source gas is being supplied through the first gas nozzle 22 and the second gas nozzle 23, or when the second source gas is being supplied through the third gas nozzle 24 and the fifth gas nozzle 26. Thereby, it is possible to improve the supply efficiency of the source gas, and to improve the gas replacement. It is also possible to suppress the backflow.

The technique of the present disclosure is described in detail by way of the embodiments mentioned above. However, the descriptions and the drawings constituting part of the present disclosure should not be understood as limiting the technique of the present disclosure. That is, the technique of the present disclosure is not limited to the embodiments mentioned above, and may be modified in various ways without departing from the scope thereof. For example, the technique of the present disclosure may be applied to other processes such as an oxidation process.

For example, the embodiments mentioned above are described by way of an example in which a batch type substrate processing apparatus capable of simultaneously processing a plurality of substrates is used to form a film. However, the technique of the present disclosure is not limited thereto. For example, the technique of the present disclosure may be preferably applied when a single wafer type substrate processing apparatus capable of simultaneously processing one or several substrates is used to form the film. For example, the embodiments mentioned above are described by way of an example in which a substrate processing apparatus including a hot wall type process furnace is used to form the film. However, the technique of the present disclosure is not limited thereto. For example, the technique of the present disclosure may be preferably applied when a substrate processing apparatus including a cold wall type process furnace is used to form the film.

Process procedures and process conditions of each process using the substrate processing apparatuses exemplified above may be substantially the same as those of the embodiments or the modified examples mentioned above. Even in such a case, it is possible to obtain substantially the same effects as in the embodiments or the modified examples mentioned above.

In addition, for example, the processing executed by the CPU 102 by reading the program (software) in the embodiments mentioned above may be executed by various processors other than the CPU 102. In such a case, for example, a PLD (Programmable Logic Device) such as an FPGA (Field Programmable Gate Array) whose circuit configuration can be changed after manufactured and a dedicated electrical circuit including a circuit configuration designed exclusively for executing a specific process such as an ASIC (Application Specific Integrated Circuit) may be used as such a processor.

For example, the processing may be executed by one of the various processors, or may be executed by a combination of two or more processors of the same or different types (for example, a plurality of FPGAs or a combination of the CPU 102 and the FPGA). More specifically, a hardware structure of each of the various processors is an electric circuit that combines circuit elements such as semiconductor devices.

For example, the embodiments mentioned above are described by way of an example in which the program for processing the substrate is stored (installed) in the memory 104 such as a ROM and a storage in advance. However, the technique of the present disclosure is not limited thereto. For example, the program may be provided in a form stored in a non-transitory storage medium (recording medium) such as a CD-ROM (Compact Disk Read Only Memory), a DVD-ROM (Digital Versatile Disk Read Only Memory) and the USB (Universal Serial Bus) memory. The program may be downloaded from an external apparatus via a network.

Furthermore, the technique of the present disclosure may be configured by partially combining configurations included in the embodiments, the modified examples and aspects mentioned above. In the technique of the present disclosure configured by such a combination, the process procedures and the process conditions of each process may be substantially the same as those of the embodiments mentioned above. Even in such a case, it is possible to obtain substantially the same effects as in the embodiments or the modified examples mentioned above. The technique of the present disclosure includes various embodiments which are not described above, and the scope of the technique of the present disclosure is defined only by specific features in the claims that are appropriate from the above descriptions.

As described above, according to some embodiments of the present disclosure, it is possible to increase the flow path area of the process gas.

What is claimed is:

1. A substrate processing apparatus comprising:
an ejection apparatus provided in a process vessel beside an edge of a substrate accommodated in the process vessel, extending along a direction perpendicular to the substrate, and configured to eject a gas onto the substrate, wherein the ejection apparatus comprises:
a first nozzle of a cylindrical shape; and
a second nozzle of a cylindrical shape, and
wherein each of the first nozzle and the second nozzle is provided with:
a flat surface facing the substrate;
two surfaces connected to both sides of the flat surface;
a plurality of first ejection holes arranged on the flat surface along a direction parallel to the substrate and configured to eject the gas substantially in a same direction; and
a second ejection hole arranged on at least one of the two surfaces and configured to eject the gas in a direction inclined with respect to the same direction.

2. The substrate processing apparatus of claim 1, wherein the first ejection holes of the first nozzle and the first ejection holes of the second nozzle are arranged on a same plane.

3. The substrate processing apparatus of claim 1, wherein each of the first nozzle and the second nozzle is configured to eject the gas in a direction substantially perpendicular to the flat surface.

4. The substrate processing apparatus of claim 1, wherein ejection holes comprising the first ejection holes and the second ejection hole of the first nozzle are arranged asymmetrically with respect to an arbitrary plane perpendicular to the substrate.

5. The substrate processing apparatus of claim 1, wherein the first nozzle and the second nozzle are configured to be symmetrical with each other with respect to a plane that substantially passes through a center of the substrate and is perpendicular to the substrate.

6. The substrate processing apparatus of claim 1, further comprising:
the process vessel comprising a first exhaust structure that opens toward and directly face at least one of the first ejection holes of the first nozzle and at least one of the first ejection holes of the second nozzle via a central axis of the substrate.

7. The substrate processing apparatus of claim 1, wherein a size of an opening of the second ejection hole is set so as not to generate a steady return flow which passes along an inner wall of the process vessel through an imaginary plane directly facing the first ejection holes on a central axis of the substrate in a direction approaching the first ejection holes.

8. The substrate processing apparatus of claim 7, wherein each of the first nozzle and the second nozzle is set such that an angle between an ejection direction of each of the first ejection holes and the second ejection hole is set to be 5° to 60°, and such that a diameter of the second ejection hole is set to be 1 mm to 4 mm.

9. The substrate processing apparatus of claim 7, wherein each of the first nozzle and the second nozzle is set such that a distance between adjacent ejection holes among the first ejection holes is set to be smaller than a distance between the second ejection hole and a first ejection hole among the first ejection holes located closest to the second ejection hole.

10. The substrate processing apparatus of claim 1, wherein a lateral width of the flat surface of each of the first nozzle and the second nozzle is set to be longer than a thickness of each of the first nozzle and the second nozzle in a direction perpendicular to the flat surface.

11. The substrate processing apparatus of claim 6, further comprising:
a plurality of second exhaust structures configured such that the gas is exhausted to an outside of the process vessel at a position farther from a plane directly facing the first ejection holes on the central axis of the substrate.

12. The substrate processing apparatus of claim 1, wherein the first nozzle and the second nozzle are configured to simultaneously eject a same gas at a substantially same flow rate.

13. The substrate processing apparatus of claim 12, wherein the substantially same flow rate is set so as to generate an unsteady return flow which passes through an imaginary plane directly facing the first ejection holes on a central axis of the substrate, excluding a vicinity of an inner wall of the process vessel, in a direction approaching the first ejection holes.

14. The substrate processing apparatus of claim 1, wherein each of the first nozzle and the second nozzle is provided with the first ejection holes and the second ejection hole arranged in a multistage manner corresponding to a plurality of substrates comprising the substrate arranged in a multistage manner with their centers aligned within the process vessel.

15. The substrate processing apparatus of claim 14, wherein cross-sectional areas of the first nozzle and the second nozzle are set such that a flow rate of the gas is lower than or equal to a predetermined flow rate at which a quadratic increase of an inner pressure from a lower stage toward an upper stage of the first ejection holes is prevented.

16. The substrate processing apparatus of claim 1, wherein the process vessel is provided with a nozzle chamber that protrudes in an outer circumferential direction and in which the first nozzle and the second nozzle are disposed, and
wherein a lateral width of the nozzle chamber is set to be within a range from 1 to 1.2 times a sum of lateral widths of the first nozzle and the second nozzle.

17. An ejection apparatus provided in a process vessel beside an edge of a substrate accommodated in the process vessel, extending along a direction perpendicular to the substrate, and configured to eject a gas onto the substrate, the ejection apparatus comprising:
a first nozzle of a cylindrical shape; and
a second nozzle of a cylindrical shape,
wherein each of the first nozzle and the second nozzle is provided with:
a flat surface facing the substrate;
two surfaces connected to both sides of the flat surface;
a plurality of first ejection holes arranged on the flat surface along a direction parallel to the substrate and configured to eject the gas substantially in a same direction; and
a second ejection hole arranged on at least one of the two surfaces and configured to eject the gas in a direction inclined with respect to the same direction.

18. A substrate processing method comprising:
(a) ejecting a gas to a substrate from an ejection apparatus provided in a process vessel beside an edge of the substrate accommodated in the process vessel and comprises a first nozzle of a cylindrical shape and a second nozzle of a cylindrical shape extending along a direction perpendicular to the substrate,
wherein each of the first nozzle and the second nozzle is provided with:
a flat surface facing the substrate;
two surfaces connected to both sides of the flat surface;
a plurality of first ejection holes arranged on the flat surface along a direction parallel to the substrate and configured to eject the gas in a substantially the same direction; and
a second ejection hole arranged on at least one of the two surfaces and configured to eject the gas in a direction inclined with respect to the substantially the same direction, and
wherein (a) comprises:
(a-1) ejecting the gas substantially in a same direction through the first ejection holes of each of the first nozzle and the second nozzle; and
(a-2) ejecting the gas in the direction inclined with respect to the same direction through the second ejection hole of each of the first nozzle and the second nozzle.

19. A method of manufacturing a semiconductor device, comprising:
the method of claim 18.

20. A non-transitory computer-readable recording medium storing a program that causes a substrate processing apparatus, by a computer, to perform a process comprising the method of claim 18.
